(19) United States
(12) Patent Application Publication
(10) Pub. No.: US 2001/0013604 A1
(43) Pub. Date: Aug. 16, 2001

(54) Compound semiconductor device and process for fabricating the same

(75) Inventor: Ichiro Hase, Kanagawa (JP)

Correspondence Address: SONNENSCHEIN NATH & ROSENTHAL, P.O. BOX 061080, WACKER DRIVE STATION, CHICAGO, IL, 60606-1080, US

(73) Assignee: Sony Corporation

(21) Appl. No.: 09/773,643

(22) Filed: Jan. 31, 2001

(30) Foreign Application Priority Data
Jan. 31, 2000 (JP) P2000-022023

(51) Int. Cl. H01L 29/06; H01L 31/0328; H01L 21/8238

(52) U.S. Cl. 257/12; 438/201

(57) ABSTRACT

A semiconductor device, comprising: a channel layer formed on a substrate, the channel layer comprising a semiconductor; a first barrier layer formed on the channel layer, the first barrier layer comprising a semiconductor which has an electron affinity smaller than that of the semiconductor constituting the channel layer; a first gate contact layer formed on the first barrier layer, the first gate contact layer having a first conductive low-resistance region which comprises a semiconductor containing a first conductive impurity in a high concentration, wherein the sum of an electron affinity and a band-gap of the first gate contact layer is larger than an electron affinity of the channel layer by 1.3 eV or more; a gate electrode formed on the first gate contact layer; and a source electrode and a drain electrode formed on the first barrier layer with the gate electrode between, wherein the channel layer serves as a current passage between the source electrode and the drain electrode. By the use of the semiconductor device of the present invention, it is possible to obtain a power amplifier having optimum low-distortion and high-efficiency performance, which is advantageous not only in that the gate threshold voltage can be controlled with a high accuracy, but also in that an operation by a single positive regulator is easy.

### BACKGROUND OF THE INVENTION

1. Field of the Invention

The present invention relates to a semiconductor device. More specifically, the present invention is related to a semiconductor device comprising a field effect transistor using a compound semiconductor of classification group III-V. The present invention is also related to a process for fabricating the above-mentioned compound semiconductor device.

2. Description of the Related Art

In a mobile communication system such as a personal handy phone system (PHS) or a personal digital cellular (PDC), strong demands have been made toward downsizing and low cost of a portable terminal, a long battery life span and the like. In order to respond to those demands, it is required, for example, for a power amplifier for transmission and a power transistor that constitutes such power amplifier to be operated with a higher current density and to have a higher power added efficiency (high efficiency). Recently, there have been strong demands toward having the power amplifier to be operable only under a positive power source. In addition, in new digital radio communication systems such as code division multiple access (CDMA) or wideband code division multiple access (WCDMA), which are expected to have increased communication quality, the above-mentioned power amplifier and power transistor are also required to have optimum low-distortion performance.

Therefore, in the power transistor for a portable radio communication terminal, it is important that the low-distortion and high-efficiency performance are optimum, that an operation under a high current density is realizable, and that an operation in an enhancement mode is easy. Especially when the power transistor can be operated in an enhancement mode, there are advantages not only in that the power transistor can be operated only by a positive power source, but also in that no drain switch is needed.

Examples of realizations of devices for the above power amplifier, which are currently practically used or being developed for practical use, include a pn junction field effect transistor (JFET), a Schottky barrier gate or metal-semiconductor field effect transistor (MESFET), a hetero-junction field effect transistor (HFET), and the like. In these conventional devices, it is not easy to realize a power field effect transistor (hereinafter, field effect transistor is frequently referred to simply as “FET”) that has an optimum low-distortion and high-efficiency performance and that can at the same time operate under a single power source.

A pn junction type hetero-junction field effect transistor (hereinafter, frequently referred to simply as “JHFET”) having an implanted p layer in a gate portion is disclosed as the above-mentioned power FET having optimum low-distortion and high-efficiency performance and that can operate under a single power source (see Japanese Patent Application Laid-Open Specification No. He-9-249217.) This JHFET is described below with reference to FIG. 8. In the further descriptions below, the names of materials are indicated using chemical symbols.

As shown in FIG. 8, in the semiconductor device, for example, a second barrier layer 113 comprising AlGaAs, a channel layer 114 comprising InGaAs and a first barrier layer 115 comprising AlGaAs are successively stacked on one another on one surface of a substrate 111 comprising a semi-insulating single crystal GaAs, through a buffer layer 112 comprising u-GaAs to which an impurity is not added intentionally. [Hereinafter, “u-” means that an impurity is not added intentionally (i.e., ‘undoped’).] Cap layers 116a, 116b are formed keeping an appropriate interval on the first barrier layer 115 at the opposite side of the substrate 111 and then, still on the opposite side of the substrate 111, an insulating film 117 is formed over the cap layers 116a, 116b and the first barrier layer 115.

An opening portion 117a is provided in the insulating film 117 in correspondence to the cap layer 116a. Then, a source electrode 118 is formed on the cap layer 116a through the opening portion 117a and, corresponding to the source electrode 118, a low-resistance region 121a is formed in the cap layer 116a and the first barrier layer 115. Likewise, an opening portion 117b is provided in the insulating film 117 in correspondence to the cap layer 116b. Then, a drain electrode 119 is formed on the cap layer 116b through the opening portion 117b and, corresponding to the drain electrode 119, a low-resistance region 121b is formed in the cap layer 116b and the first barrier layer 115.

In addition, an opening portion 117c is provided in the insulating film 117 and a gate electrode 120 is formed on the first barrier layer 115 through the opening portion 117c.

The first barrier layer 115 has a region 115a to which an n-type impurity is added in a high concentration, a high-resistance region 115b to which an impurity is not added intentionally, and a first conductive low-resistance region 115c facing the gate electrode 120 and to which a p-type impurity is added in a high concentration.

The second barrier layer 113 has a region 113a to which an n-type impurity is added in a high concentration, and a high-resistance region 113b to which an impurity is not added intentionally. Each of the cap layers 116a, 116b contains an n-type impurity in a high concentration. In addition, the channel layer 114 serves as a current passage between the source electrode 118 and the drain electrode 119.

Since the above-mentioned semiconductor device employs a junction gate structure, it exhibits a high built-in voltage compared to a conventional device employing a Schottky junction gate, so that a large positive voltage can be applied to the gate electrode 120. Therefore, it becomes easy to operate the semiconductor device described above only by a positive power source.

In addition, in the above semiconductor device, as the first conductive low-resistance region 115c is implanted in the first barrier layer 115, the source resistance of the semiconductor device having such a structure is easily reduced, as compared to a Schottky barrier gate type field effect transistor (MESFET) having a recess structure. Therefore, such a semiconductor device has an advantage from the viewpoint of reducing the on-state resistance and increasing the power added efficiency. The above semiconductor device is particularly suitable for operation in an enhancement mode.

Further, as mentioned above, in the above semiconductor device, as a high positive voltage can be applied to the gate electrode 120, and a discontinuity amount ΔE_{c} of a conduction band edge between the channel layer 114 and the first barrier layer 115 being large, a fluctuation in a gate-source capacitance C_{gs} and a fluctuation in a mutual conductance Gₘ are small over a wide range of the gate voltage. Thus, the semiconductor device has also an optimum low-distortion performance. In addition, the large discontinuity amount ΔE_{c} allows the current density to be increased.

Next, an example of a semiconductor device having in principle a more optimized structure than the JHFET shown in FIG. 8 from the viewpoint of achieving an easier control of a gate threshold voltage Vₜₕ is described below with reference to FIG. 9. The example shows a JHFET having a structure in which a pn junction gate is formed by a process that follows a preliminarily formation of a p layer through an epitaxial growth process. Hereinafter, such semiconductor device is referred to as “EJHFET”.

For example, as shown in FIG. 9, in the EJHFET, on one surface of a substrate 111 comprising a semi-insulating single crystal GaAs, a second barrier layer 113 comprising AlGaAs, a channel layer 114 comprising InGaAs, a first barrier layer 122 comprising AlGaAs and a gate contact layer 123 comprising p-GaAs are successively stacked on one another over a buffer layer 112 comprising u-GaAs to which an impurity is not added intentionally. Then, on the opposite side of the substrate 111, an insulating film 117 is formed on the first barrier layer 122.

Opening portions 117a and 117b are provided through the insulating film 117. A source electrode 118 and a drain electrode 119 are formed on the first barrier layer 122, respectively in the opening portions 117a and 117b. Low-resistance regions 121a and 121b respectively corresponding to the source electrode 118 and the drain electrode 119 are formed in the first barrier layer 122. Further, an opening portion 117c is provided in the insulating film 117. A gate electrode 120 is then formed on the gate contact layer 123 through the opening portion 117c.

The first barrier layer 122 comprises a region 122a to which a high concentration n-type impurity is added, and a high-resistance region 122b to which an impurity is not added intentionally. Likewise, the second barrier layer 113 comprises a region 113a to which a high concentration n-type impurity is added, and a high-resistance region 113b to which an impurity is not added intentionally. A high concentration p-type impurity is added to the gate contact layer 123. The channel layer 114 serves as a current passage between the source electrode 118 and the drain electrode 119.

In the above semiconductor device, for the same reasons as mentioned concerning the JHFET above, it is expected that an operation only by a positive power source is easy, the low-distortion performance is optimum, and the current density can be increased.

Although the JHFET described above with reference to FIG. 8 having several optimum properties, from the viewpoint of its construction, the first conductive low-resistance region is formed in the diffusion layer, making it difficult to control the diffusion layer depth with high accuracy. Thus, the JHFET has a disadvantage that it is not easy to control the gate threshold voltage Vₜₕ.

In addition, the EJHFET described above with reference to FIG. 9 has the following problems to be solved. According to a general process for fabricating a semiconductor device, as for forming source and drain electrodes, it is necessary in the vicinity of the source and drain electrodes to remove a gate contact layer that comprises p-GaAs. In a region in which the gate contact layer is removed, a distance between the uppermost surface of the semiconductor and the channel layer is small, thus making the channel layer is susceptible to be affected by the surface. Specifically, the channel layer is affected by the surface level inherent to the GaAs surface, as well as defects, contamination and the like that may occur in the vicinities of the surface during a process of fabricating the semiconductor including the formation of an insulating film and the like, so that a carrier density of the channel layer is reduced and a resistance between the source and gate electrodes is susceptible to increase. Especially in the enhancement mode FET, even when it is manufactured in an ideal condition, the channel layer beneath the region in which the gate contact layer comprising p-GaAs has been removed has inherently only a reduced amount of carriers, so that the above phenomenon is more remarkable. This problem is severe, even as compared to the case of the JHFET structure described above with reference to FIG. 8.

### SUMMARY OF THE INVENTION

It is an object of the present invention to provide a semiconductor device and a process for fabricating the same in order to solve the above-mentioned problems accompanying the related art The semiconductor device of this invention comprises: a channel layer formed on a substrate, the channel layer comprising a semiconductor that operates as a current passage between a source electrode and a drain electrode; a first barrier layer formed on the channel layer, the first barrier layer comprising a semiconductor having an electron affinity smaller than that of the semiconductor constituting the channel layer; a first gate contact layer formed on the first barrier layer, the first gate contact layer having a first conductive low-resistance region which comprises a semiconductor containing a first conductive impurity in a high concentration, wherein the sum of an electron affinity and a band-gap of the first gate contact layer is larger than an electron affinity of the channel layer by 1.3 eV or more; a gate electrode formed on the first gate contact layer; and a source electrode and a drain electrode formed on the first barrier layer with the gate electrode interposed.

By using the semiconductor device explained above, it is possible to obtain a power amplifier having optimum low-distortion and high-efficiency performance, which is advantageous not only in that the gate threshold voltage can be controlled with a high accuracy, but also in that an operation by a single positive power source is easy. The present invention has been completed, based on the above novel finding.

Accordingly, it is an object of the present invention to provide a semiconductor device which is advantageous in that a power amplifier having optimum low-distortion and high-efficiency performance and not only permitting a high accuracy in a gate threshold voltage control, but also an easy operation under a single positive power source.

It is another object of the present invention to provide a process for fabricating the above-mentioned optimum semiconductor device.

### BRIEF DESCRIPTION OF THE DRAWINGS

The foregoing and other objects, features and advantages of the present invention will be apparent to those skilled in the art from the following description of the presently preferred exemplary embodiments of the invention taken in connection with the accompanying drawings, in which:

FIG. 1 is a diagrammatic cross-sectional view of a semiconductor device according to the first embodiment of the present invention;

FIG. 2 is a diagrammatic view showing an energy band structure under the gate electrode of the semiconductor device of the first embodiment of the present invention in a state such that a gate voltage V_{g} is not applied;

FIG. 3 is a diagrammatic view showing an energy band structure under the gate electrode of the semiconductor device of the first embodiment of the present invention in a state such that a gate voltage V_{g} of 1.2 V or more is applied;

FIG. 4 is a graph showing the correlation between a drain current I_{d} and a gate voltage V_{g} of a semiconductor device;

FIG. 5 is a graph showing the correlation between a mutual conductance Gₘ and a gate voltage V_{g} of a semiconductor device;

FIGS. 6A to 6D are diagrammatic cross-sectional views showing a process for fabricating a semiconductor device according to one embodiment of the present invention;

FIG. 7 is a diagrammatic cross-sectional view of a semiconductor device according to the second embodiment of the present invention;

FIG. 8 is a diagrammatic cross-sectional view of a conventional pn junction hetero-junction field effect transistor (JHFET); and

FIG. 9 is a diagrammatic cross-sectional view of a conventional pn junction hetero-junction field effect transistor (EJHFET) using epitaxial growth.

### DESCRIPTION OF THE PREFERRED EMBODIMENTS

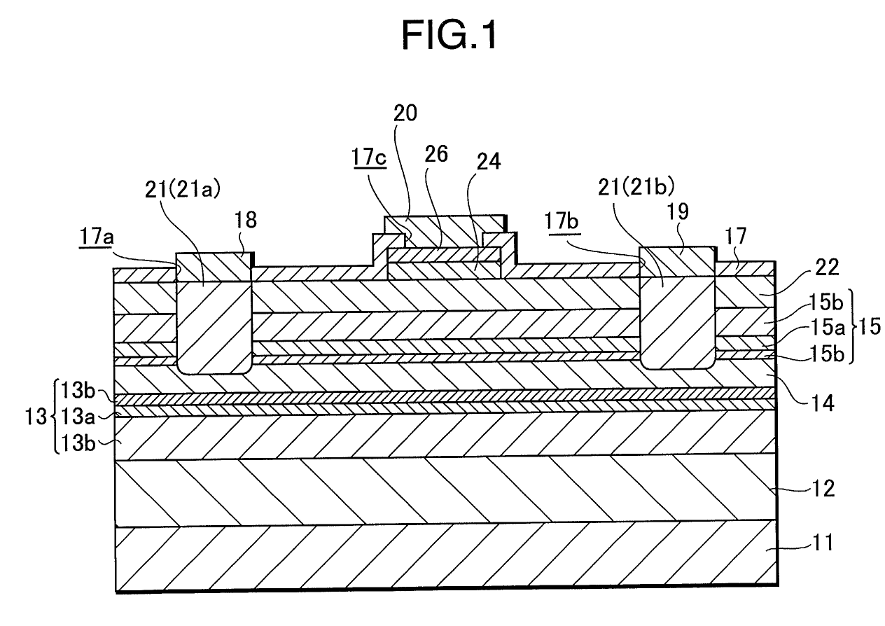

Hereinafter, a first embodiment of a semiconductor device of the present invention will be described in detail with reference to the diagrammatic cross-sectional view of FIG. 1. However, the embodiment should not be construed as to limiting the scope of the present invention. FIG. 1 shows an example of an n-channel type FET in which the first conductive impurity is of a p-type and the second conductive impurity is of an n-type.

As shown in FIG. 1, in the semiconductor device, for example a second barrier layer 13, a channel layer 14, a first barrier layer 15, a third barrier layer 22, a first gate contact layer 24 and a second gate contact layer 26, each of which comprising a III-V compound semiconductor, are successively stacked on one another on one surface of a substrate 11 comprising a semi-insulating single crystal GaAs through a buffer layer 12 comprising u-GaAs to which an impurity is not added intentionally [Hereinafter, “u-” means that an impurity is not added intentionally (i.e., ‘undoped’).]. On the third barrier layer 22 and on the first and second gate contact layers 24, 26 on the side opposite to the substrate 11, a portion exposed to the outside is covered with an insulating film 17.

Opening portions 17a and 17b are provided in the insulating film 17. A source electrode 18 and a drain electrode 19 are formed on the third barrier layer 22 through the opening portions 17a and 17b, respectively. In addition, an opening portion 17c is provided between the opening portion 17a and the opening portion 17b in the insulating film 17. A gate electrode 20 is then formed on the second gate contact layer 26 through the opening portion 17c.

The second barrier layer 13 comprises a III-V compound semiconductor having an electron affinity smaller and a band-gap wider than that of the III-V compound semiconductor which constitutes the channel layer 14. A GaAs or InGaAs compound crystal or the like is used in the channel layer 14. As an example of the III-V compound semiconductor having an electron affinity smaller and a band-gap wider than that of the GaAs or InGaAs compound crystal, there is an AlGaAs compound crystal, and the second barrier layer 13 comprises, for example, an Al_{0.23}Ga_{0.77}As compound crystal in which the atomic ratio of aluminum (Al) of the elements of Group III is 0.23.

In addition, the second barrier layer 13 has a high-concentration impurity addition second conductive region 13a to which an n-type impurity which is a second conductive impurity is added in a high concentration, and a low impurity-concentration region 13b having a low impurity concentration and a high resistance. In this embodiment, the second barrier layer 13 has a structure such that, for example, the low impurity-concentration region 13b having a thickness of 200 nm and to which no impurity has been added, the second conductive addition region 13a having a thickness of 3 nm to which silicon as an n-type impurity is added in a concentration of, for example, about 1.4×10¹² particles/cm², and the low impurity-concentration region 13b having a thickness of 2 nm and to which no impurity has been added are successively stacked on one another in this order from the side of the substrate 11. Finally, the low impurity-concentration region 13b may contain a small amount of an impurity compared to the second conductive addition region 13a. As the n-type impurity of the second conductive impurity, selenium, germanium, tin, sulfur and the like can be used other than silicon.

The channel layer 14 operates as a current passage between the source electrode 18 and the drain electrode 19, and comprises a III-V compound semiconductor having an electron affinity larger and a band-gap narrower than that of the III-V compound semiconductor which constitutes each of the second barrier layer 13. An InGaAs compound crystal and the like can be mentioned as examples of the III-V compound semiconductor having a large electron affinity and a narrow band-gap. In this embodiment, the channel layer 14 comprises, for example, an u-In_{0.2}Ga_{0.8}As compound crystal in which the atomic ratio of indium (In) of the Group III elements is 0.2 and to which an impurity is not added. Thus, it is possible to store a carrier in the channel layer 14.

When the channel layer 14 comprises an InGaAs compound crystal, it is desirable that the atomic ratio of In of the Group III elements is equal or more than 0.1 and equal or less 0.4. The higher the atomic ratio of In, the larger the electron affinity, and the narrower the band-gap. Therefore, when the atomic ratio of In of the Group III elements is 0.1 or more, a difference in each conduction band edge between the second barrier layer 13 and the channel layer 14 and a difference in conduction band edge between the first barrier layer 15 and the channel layer 14 can be individually increased satisfactorily. On the other hand, when the atomic ratio of In of the Group III elements exceeds 0.4, the lattice mismatch between the channel layer 14 and GaAs or AlGaAs becomes too large. Therefore, it is desirable that the atomic ratio of In of the Group III elements is adjusted so as to fall within the above range.

It is desirable that the thickness of the channel layer 14 is 18 nm or less. This is because, when the channel layer 14 has a larger thickness, the properties of the channel layer as a crystal becomes poor.

The first barrier layer 15 comprises a III-V compound semiconductor having an electron affinity smaller and a band-gap wider than that of the III-V compound semiconductor which constitutes the channel layer 14. When the channel layer 14 comprises InGaAs, InGaP, AlInGaP and AlGaAs compound crystals and the like can be mentioned as examples of the III-V compound semiconductor which constitutes the first barrier layer 15. Each of these compound crystals individually have their advantages, however, in this embodiment, for example, the first barrier layer 15 comprises an Al_{0.23}Ga_{0.77}As compound crystal in which the atomic ratio of Al of the Group III elements is 0.23.

In this embodiment, the second barrier layer 13 and the first barrier layer 15 comprise the same composition of Al_{0.23}Ga_{0.77}As compound crystal, but it is possible to use AlGaAs compound crystals having different compositions. In the first barrier layer 15, as for reducing the source resistance, it is desirable that the atomic ratio of Al of the Group III elements is 0.25 or less. On the other hand, in the second barrier layer 13, the atomic ratio of Al of the Group III elements does not necessarily fall in the above range, and from the viewpoint of suppressing the current flowing on the substrate side, it may be desirable that the atomic ratio of Al of the Group III elements is slightly higher. In addition, when the first barrier layer 15 is formed by an InGaP compound crystal, it is desirable that the atomic ratio of In in the Group III elements is equal or more than 0.4 and equal or less than 0.6. When the atomic ratio of In in the Group III elements is less than 0.4 or more than 0.6, the lattice mismatch between the first barrier layer 15 and the GaAs substrate becomes too large.

The first barrier layer 15 has a second conductive high-concentration impurity addition region 15a containing an n-type impurity in a high concentration, and a low impurity-concentration region 15b having a low impurity concentration and a high resistance. In this embodiment, the first barrier layer 15 has a structure such that, for example, the low impurity-concentration region 15b having a thickness of 2 nm and to which no impurity has been added, the second conductive high-concentration impurity addition region 15a having a thickness of 6 nm to which silicon is added as an n-type impurity in a concentration of, for example, about 2.7×10¹² particles/cm², and the low impurity-concentration region 15b having a thickness of 4 nm and to which no impurity has been added are successively stacked on one another from the side of the channel layer 14. Furthermore, the low impurity-concentration region 15b may contain a small amount of an impurity, as compared to the second conductive high-concentration impurity addition region 15a. As the n-type impurity of the second conductive impurity, selenium, germanium, tin, sulfur and the like can be used other than silicon.

It is desirable that the concentration of the impurity in the low impurity-concentration regions 13b, 15b is 2×10¹⁷ particles/cm³ or less. When the concentration exceeds this value, the electron transit speed through the channel layer 14 is remarkably lowered in a region adjacent to the channel layer 14, and in a region near the gate, the gate voltage endurance is remarkably lowered.

The first gate contact layer 24 comprises a p-type III-V compound semiconductor of which the sum of an electron affinity and a band-gap is larger than the electron affinity of the channel layer 14 by 1.3 eV or more. Thus, a gate built-in voltage as large as 1.3 eV or more can be yielded, assuring a desired gate threshold voltage Vₜₕ to be obtained, making it possible to add an n-type impurity in a higher concentration to each of the first barrier layer 15 and the second barrier layer 13. As a result, an increase in source resistance can be restrained.

In this embodiment, the first gate contact layer 24 comprises a p-Al_{0.35}Ga_{0.65}As compound crystal in which the atomic ratio of Al of the Group III elements is 0.35. When the channel layer 14 comprises an u-In_{0.2}Ga_{0.8}As compound crystal, the sum of the electron affinity and the band-gap of the first gate contact layer 24 exceeds the electron affinity of the channel layer 14 by about 1.44 eV. This value exceeds the value of a conventional construction by 0.1 eV or more, such conventional construction in which p-GaAs is used in the first gate contact layer 24 and an u-In_{0.2}Ga_{0.8}As compound crystal is used in the channel layer 14.

In this embodiment, by using the p-Al_{0.35}Ga_{0.65}As compound crystal in the first gate contact layer 24, the added concentration of the n-type impurity in the first barrier layer 15 has been increased by about 13%, as compared to the case in which p-GaAs is used for the same film thickness. An explanation is made herein on the case in which the atomic ratio of Al of the Group III elements is 0.35, however, the larger the atomic ratio of Al of the Group III elements, the larger the above n-type impurity concentration, thus making the effect larger. As for obtaining such an effect, it is desirable that the atomic ratio of Al of the Group III elements is 0.3 or more. However, generally, when the atomic ratio of Al is too high, as a problem arises in that AlGaAs becomes more susceptible to oxidation, it is desirable that the atomic ratio of Al of the Group III elements is 0.7 or less. Accordingly, it is desirable that the atomic ratio of Al of the Group III elements is set to be equal or more than 0.3 and equal or less than 0.7.

As for the p-Al_{0.35}Ga_{0.65}As compound crystal constituting the first gate contact layer 24, the p-type impurity concentration is 7×10¹⁸ particles/cm³, and the thickness is 50 nm. It is desirable that the p-type impurity concentration is 1×10¹⁸ particles/cm³ or more. When the concentration is lower than this value, the depletion layer width becomes inconveniently large. In addition, at least one element selected from carbon, zinc, germanium and beryllium can be used as the p-type impurity (first conductive impurity).

The third barrier layer 22 comprises a III-V compound semiconductor of which the sum of an electron affinity and a band-gap is larger than that of the first gate contact layer 24. The reason why the electron affinity and the band-gap are increased resides in that a p-type carrier is sealed within the first gate contact layer 24 in order to restrain a leakage of the carrier to the first barrier layer 15 to the lowest amount as possible. When the sum of the electron affinity and the band-gap of the third barrier layer 22 is smaller than that of the first gate contact layer 24, the p-type carrier is sealed within the third barrier layer 22. As a result, the built-in voltage in the pn junction becomes small, so that the expected effect of using, as the first gate contact layer 24, a III-V compound semiconductor of which the sum of an electron affinity and a bandgap is larger than that of the channel layer 14 by 1.3 eV or more cannot be obtained.

InGaP and AlGaInP are conventionally used as the III-V compound semiconductor of which the sum of an electron affinity and a band-gap is larger than that of the first gate contact layer 24 that comprises AlGaAs. In this embodiment, u-InGaP having a thickness of 8 nm and a lattice constant consistent with that of GaAs, in which the atomic ratio of In of the Group III elements is about 0.5, is used as the third barrier layer 22. When AlGaAs is used in the first gate contact layer 24 and InGaP is used in the third barrier layer 22, it is possible to selectively remove the first gate contact layer 24, and this is advantageous from the viewpoint of fabrication of devices. In the InGaP used in this embodiment, it is desirable that the atomic ratio of In of the Group III elements is from 0.4 to 0.6. When the atomic ratio of In of the Group III elements is lower than 0.4 or higher than 0.6, the lattice mismatch between the third barrier layer 22 and the GaAs substrate becomes too large.

The second gate contact layer 26 comprises a III-V compound semiconductor capable of decreasing the gate contact resistance to be lower, as compared to that in the case in which the gate electrode 20 is formed on the first gate contact layer 24. Generally, such a compound semiconductor is a III-V compound semiconductor of which the sum of an electron affinity and a band-gap is smaller than that of the first gate contact layer 24. When the first gate contact layer 24 comprises AlGaAs, it is desirable that the second gate contact layer 26 comprises GaAs. In this case, not only can the gate contact resistance be lowered, but also an effect of restraining the oxidation of the semiconductor surface can be obtained, as compared to the case in which the gate electrode 20 is formed over AlGaAs.

In this embodiment, the thickness of the second gate contact layer 26 is 50 nm, and carbon is added as a p-type impurity (first conductive impurity), in a concentration on the order of 2×10¹⁹ particles/cm³. Zinc, magnesium, beryllium and the like can be used as the p-type impurity other than carbon.

The insulating film 17 comprises, for example, a silicon nitride (Si₃N₄) film having a thickness of 200 nm.

The gate electrode 20 has a construction such that titanium (Ti), platinum (Pt) and gold (Au) are stacked on one another in this order from the substrate 11 side.

The source electrode 18 and the drain electrode 19 are formed by a method in which AuGe, nickel (Ni) and Au are successively stacked on one another in this order from the substrate 11 side and, then, the source is at least partially alloyed with the semiconductor portion by a thermal treatment at around 400° C. A low-resistance region 21 (21a, 21b) is a low-resistance region that is formed inside the third barrier layer 22, the first barrier layer 15 and the channel layer 14 during the above alloying process. The source electrode 18 and the drain electrode 19 are connected to the channel layer 14 by means of an ohmic contact through the low-resistance region 21, and these kinds of electrodes are generally referred to as ohmic electrodes. In addition, the low-resistance region 21 may either pass through the channel layer 14 and reach the second barrier layer 13, or may not reach the channel layer 14.

Finally, in this embodiment, the ohmic electrode is formed from AuGe, Ni and Au, however, the ohmic electrode may be formed from other metals. In addition, the low-resistance region 21 is formed from alloying the ohmic electrodes, however the low-resistance region 21 may be formed by diffusion or ion implantation of an impurity prior to the formation of the source electrode 18 and the drain electrode 19. Further, for example, metals such as In and the like, may be preliminarily alloyed to form the low-resistance region 21, and then, the source electrode 18 and the drain electrode 19 are formed. Yet, in a region in which the third barrier layer 22 is formed on the uppermost surface of the semiconductor layers between the gate electrode 20 and the source electrode 18, a layer containing at least one element selected from selenium, sulfur and silicon in a high concentration can be formed on the surface layer portion of the third barrier layer 22.

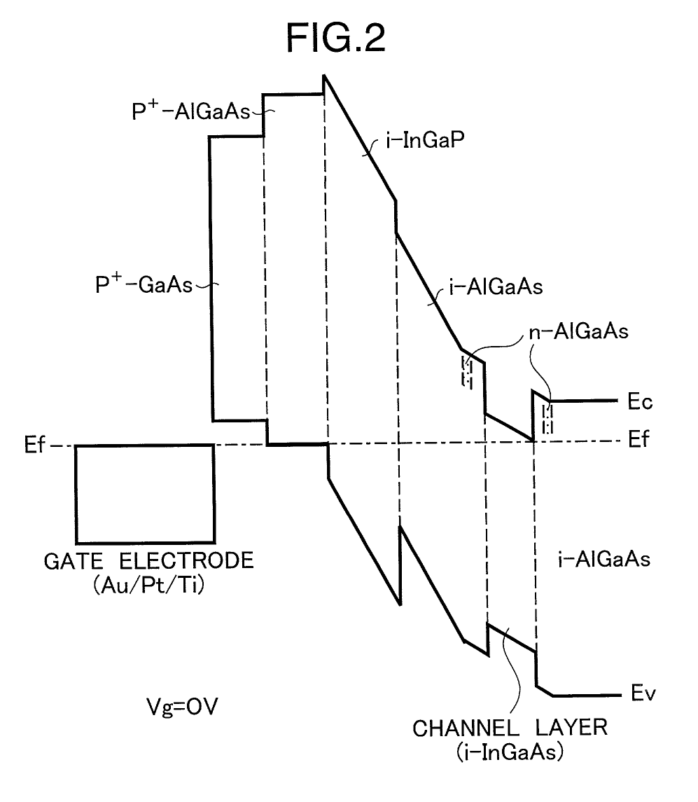

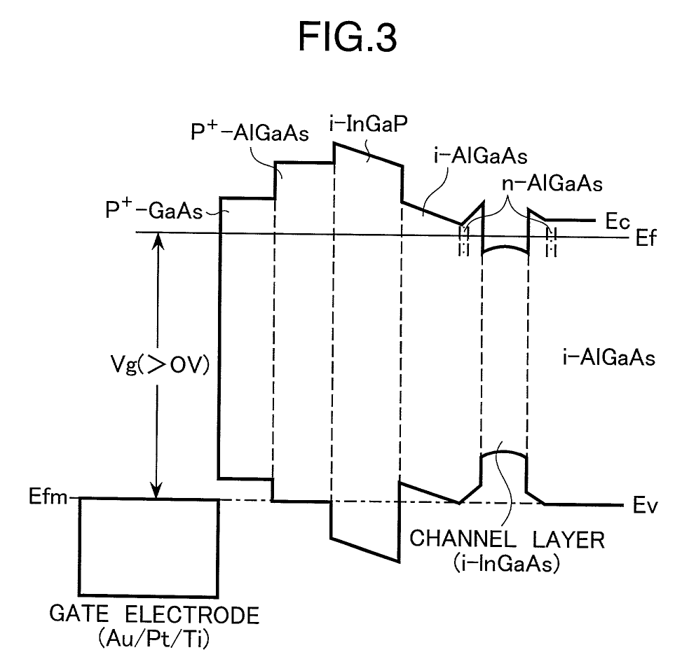

Each of FIGS. 2 and 3 shows an energy band structure under the gate electrode 20 of the semiconductor device described in the first embodiment of the present invention. FIG. 2 shows an energy band structure in a state in which a gate voltage V_{g} is not applied, and FIG. 3 shows one in a state in which a gate voltage V_{g} of 1.2 V or more is applied. In addition, each of FIGS. 2 and 3 shows an energy band structure in the case in which each of the second barrier layer 13 and the first barrier layer 15 comprises an Al_{0.23}Ga_{0.77}As compound crystal, the third barrier layer 22 comprises an In_{0.5}Ga_{0.5}P compound crystal, the first gate contact layer 24 comprises a p⁺-Al_{0.35}Ga_{0.65}As compound crystal, the second gate contact layer 26 comprises p⁺-GaAs, and the channel layer 14 comprises an In_{0.2}Ga_{0.8}As compound crystal.

In such a semiconductor device, p⁺-Al_{0.35}Ga_{0.65}As is used in the first gate contact layer 24, and hence, the sum of the electron affinity and the band-gap of the first gate contact layer 24 is larger than the electron affinity of In_{0.2}Ga_{0.8}As which constitutes the channel layer 14 by 1.4 eV or more. Therefore, the built-in voltage can be increased and a large positive voltage can be applied to the gate electrode 20, as compared to the case in which p⁺-GaAs is used in the first gate contact layer 24. At the same time, it becomes possible to add an n-type impurity to the first barrier layer 15 in a higher concentration. Thus, it becomes possible to restrain an increase in source resistance. As shown in FIG. 3, even when a gate voltage V_{g} of, for example, 1.3 eV or more is applied, the height of the barrier in the direction of the gate electrode 20, as viewed from the channel layer 14, can be kept sufficiently high as to restrain the gate leakage current.

In addition, u-InGaP is used in the third barrier layer 22, and as the sum of the electron affinity and the band-gap of the third barrier layer 22 is larger than that of the first gate contact layer 24, a p-type carrier does not move from the first gate contact layer 24 containing a p-type impurity to the third barrier layer 22, and is still sealed in the first gate contact layer 24, so that the above-mentioned large built-in voltage can be realized.

When, for example, GaAs, of which the sum of an electron affinity and a band-gap is smaller than that of the first gate contact layer 24, is used in the third barrier layer 22, or when the third barrier layer 22 is omitted and the first gate contact layer 24 is directly formed on Al_{0.23}Ga_{0.77}As which is the first barrier layer 15, a p-type carrier moves from the first gate contact layer 24 containing a p-type impurity to the third barrier layer 22 or the first barrier layer 15, so that it is not possible to obtain the expected effect by using Al_{0.35}Ga_{0.65}As having a large electron affinity and band-gap in the first gate contact layer 24.

In addition, as p-GaAs to which a p-type impurity is added in a concentration as high as 2×10¹⁹ particles/cm³ is used in the second gate contact layer 26, the gate contact resistance can be kept low.

Further, like the JHFET and EJHFET described in “Related Art” above, in the semiconductor device of this embodiment, as the discontinuity amount ΔE_{c} of conduction band edge between the channel layer 14 and the first barrier layer 15 is satisfactorily large (about 0.33 eV in this case), this semiconductor device has a construction such that a difference between the minimal value of the potential of the first barrier layer 15 and the quasi-Fermi level of the electrons in the channel layer 14 is satisfactorily large (0.20 eV or more in this case), so that the number of electrons distributed in the first barrier layer 15 is as small as it can be ignored, as compared to the number of electrons distributed in the channel layer 14. In other words, the amount of the current flowing through the first barrier layer 15 during the operation of the device is as small as it can be ignored, as compared to the amount of the current flowing through the channel layer 14, and the transit of little electrons through the first barrier layer 15 having a mobility lower than that of the channel layer 14 prevents the mutual conductance Gₘ from suffering deterioration. Such a state is kept for a gate voltage V_{g} up to around 1.4 V.

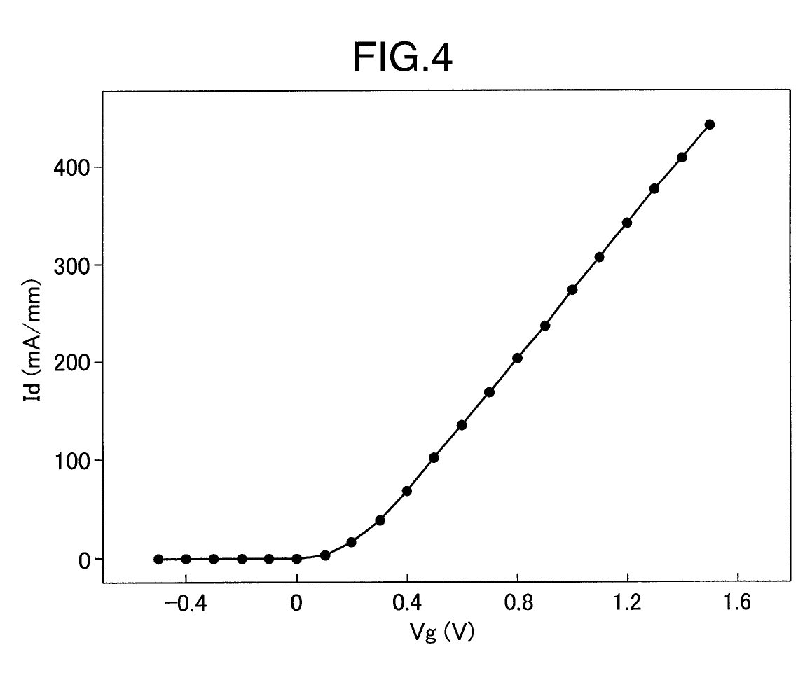

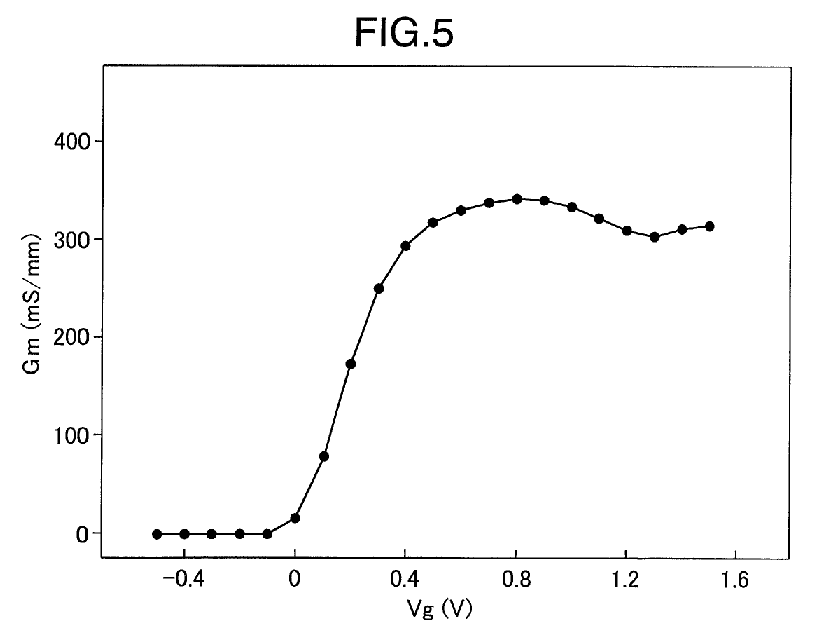

With respect to the semiconductor device in this embodiment, FIG. 4 shows the relationship between a drain current I_{d} (mA/mm) and a gate voltage V_{g} (V), and FIG. 5 shows the relationship between a mutual conductance Gₘ (mS/mm) and a gate voltage V_{g} (V). FIGS. 4 and 5 shows respectively the relationships in the case where each of the second barrier layer 13 and the first barrier layer 15 comprises an Al_{0.23}Ga_{0.77}As compound crystal, and the channel layer 14 comprises an In_{0.2}Ga_{0.8}As compound crystal.

As shown in FIGS. 4 and 5, this semiconductor device is operated in an enhancement mode in which the gate threshold voltage Vₜₕ is about 0 V, and has a feature such that a gate voltage V_{g} of up to 1.4 V can be applied, and, a dependence of the mutual conductance Gₘ on the gate voltage V_{g} is small over this wide range of the gate voltage. In addition, the semiconductor device has the same advantages as those of the above two devices described in “Related Art”, i.e., advantages in that an operation only by a positive power supply is easy and a power device having optimum low-distortion properties can be realized.

Further, by virtue of having a construction such that the fabrication process of the p-type gate is easy and an increase in source resistance can be restrained, a so-called on-state resistance Rₒₙ can be kept low. Therefore, when the semiconductor device of this embodiment is used as a power transistor, it is possible to realize a device having optimum high-efficiency properties. Still, when the semiconductor device is used as a switch, it is possible to realize a low loss device.

Yet, the semiconductor device of this embodiment is operated as follows. In this semiconductor device, as the gate threshold voltage Vₜₕ is about 0 V, and from the fact that the first gate contact layer 24 is of a p-type in a state such that no voltage is applied to the gate electrode 20 (V_{g}=0 V), the electrons in the region of the channel layer 14 immediately under the first gate contact layer 24 are either almost completely depleted, or the channel layer 14 lacks electrons as compared to other regions, so that the channel layer 14 is in a state of high resistance. When a positive gate voltage V_{g} of about 1.0 V, for example, is applied to the gate electrode 20, the electron-lacking region disappears, and, according to the energy band diagram shown in FIG. 3, the number of the electrons in the channel layer 14 is increased. As a result, the drain current I_{d} is modulated.

In this embodiment, an explanation is made on the case of an enhancement mode, but the same explanation can also be made on the case of a depletion mode.

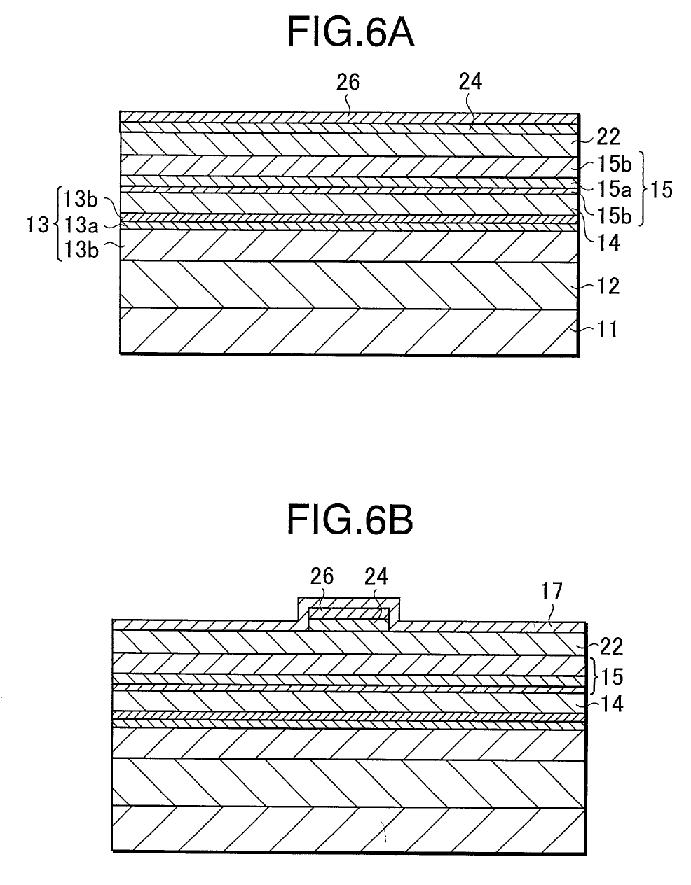

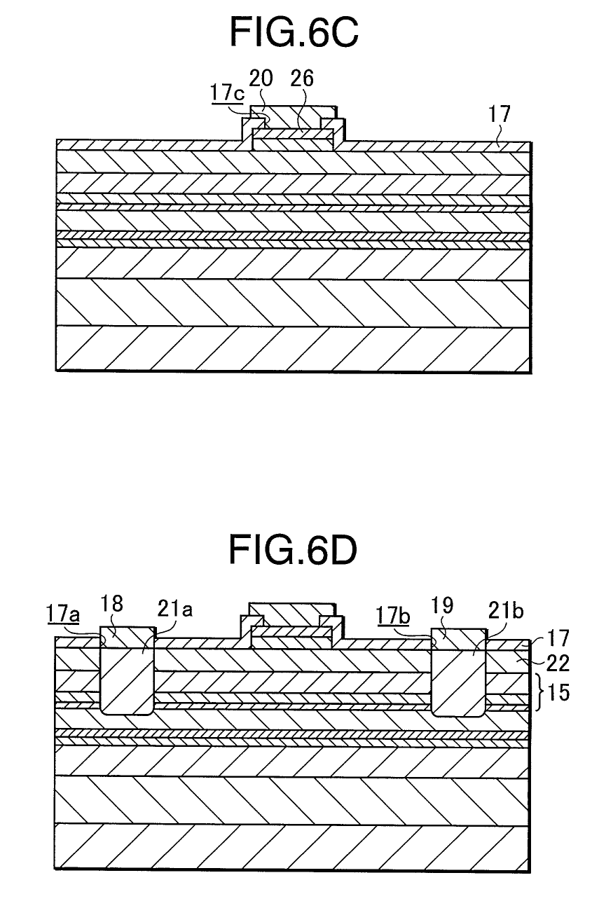

Next, the process for fabricating a semiconductor device according to one embodiment of the present invention will be described below in detail with reference to the diagrammatic cross-sectional views of FIGS. 6A to 6D.

As shown in FIG. 6A, for example, on a substrate 11 comprising GaAs for example, an u-GaAs layer to which no impurity has been added is allowed to undergo epitaxial growth to form a buffer layer 12, and then, on the buffer layer 12, for example an u-AlGaAs layer to which no impurity has been added, an n-type AlGaAs layer and an u-AlGaAs layer to which no impurity has been added are successively allowed to undergo epitaxial growth, to thereby form a second barrier layer 13 in which a low impurity-concentration region 13b, a second conductive high-concentration impurity addition region 13a and a low impurity-concentration region 13b are stacked on one another.

Next, on the second barrier layer 13, for example an u-InGaAs layer to which no impurity has been added is allowed to undergo epitaxial growth to form a channel layer 14. Then, on the channel layer 14, for example an u-AlGaAs layer to which no impurity has been added, an n-type AlGaAs layer to which silicon as an n-type impurity is added, and an u-AlGaAs layer to which no impurity has been added are successively allowed to undergo epitaxial growth, to thereby form a low impurity-concentration region 15b, a second conductive high-concentration impurity addition region 15a and a low impurity-concentration region 15b of a first barrier layer 15. Subsequently, on the first barrier layer 15, an u-InGaP layer to which no impurity has been added is allowed to undergo epitaxial growth to form a third barrier layer 22. Further, on the third barrier layer 22, for example a p-type AlGaAs layer to which carbon as a p-type impurity is added and a p-type GaAs layer, are successively allowed to undergo epitaxial growth, to thereby form a first gate contact layer 24 and a second gate contact layer 26.

Then, as shown in FIG. 6B, using both a lithography technique and an etching technique, the first gate contact layer 24 and the second gate contact layer 26 are selectively removed, excluding a region on which a gate electrode will be formed.

Subsequently, an insulating film 17 is formed on the third barrier layer 22, the second gate contact layer 26 and the sidewalls of the first and second gate contact layers 24 and 26 by a deposition of, for example, a silicon nitride film by means of a chemical vapor deposition (CVD) process.

Then, although not shown in the figure, a separation between devices is performed by either a mesa etching or an ion implantation of oxygen, boron or the like. Next, as shown in FIG. 6C, a part of the insulating film 17 in the region of the second gate contact layer 26 is selectively removed by means of an etching process, to thereby form an opening portion 17c in the region on which a gate electrode will be formed. Then, for example Ti, Pt and Au are successively deposited on the opening portion 17c through a vapor deposition process. Then, the above metal films are subjected to a patterning, to thereby form a gate electrode 20.

Then, as shown in FIG. 6D, the insulating film 17 is selectively removed from a region on which source and drain electrodes will be formed, by means of an etching process, to thereby form opening portions 17a and 17b, respectively in the region on which a source electrode will be formed and the region on which a drain electrode will be formed. Then, for example AuGe, Ni and Au are successively deposited on the opening potions 17a and 17b through a vapor deposition process. Then, the above metal films are subjected to patterning. Subsequently, the metal films are alloyed by a thermal treatment of about 400° C. to form an Au alloy, so that a source electrode 18 and a drain electrode 19, and corresponding low-resistance regions 21a and 21b are formed, for example, in the third barrier layer 22 and the first barrier layer 15, thus completing the semiconductor device shown in FIG. 1. According to the semiconductor device of the preferred embodiment of the present invention and the process for fabricating the same, since the p-type second gate contact layer 26 and the p-type first gate contact layer 24, corresponding to the gate electrode 20, are not in contact with the semiconductor to which an n-type impurity is added, the voltage endurance between the gate electrode 20 and the drain electrode 19 can be improved. Therefore, the semiconductor device of the present invention can be advantageously used as a power amplifier, for example, as a power amplifier for a mobile communication system. Particularly, when a semiconductor capable of increasing the electron velocity, such as InGaAs or the like is used in a channel, the radio communication device obtained has optimum high-frequency characteristics, and hence, it is advantageously used in a communication frequency at a high frequency band, especially ultra high frequency (UHF) band or higher.

In addition, in the semiconductor device of the preferred embodiment of the present invention and the process for fabricating the same, the first barrier layer 15 comprising a semiconductor having an electron affinity smaller than that of the semiconductor which constitutes the channel layer 14 and having a band-gap wider than that of this semiconductor is provided between the channel layer 14 and the gate electrode 20. Consequently, a dependence of the mutual conductance Gₘ and the gate-source electrode capacitance C_{gs} on the gate voltage V_{g} becomes small. Further, in this semiconductor device, the maximal voltage that can be applied to the gate can be increased. Therefore, a change in the mutual conductance Gₘ and in the gate-source capacitance C_{gs} are small over a wide range of the gate voltage, and as a result, the distortion properties are improved.

In addition, by providing the first barrier layer 15 comprising a semiconductor having an electron affinity smaller and a band-gap wider than that of the semiconductor that constitutes the channel layer 14 and so as to be in contact with the channel layer 14, the current density can be increased.

Further, since a semiconductor of which the sum of an electron affinity and a band-gap is larger than the electron affinity of the channel layer 14 by 1.3 eV or more is used in the first gate contact layer 24, and a semiconductor of which the sum of an electron affinity and a band-gap is larger than that of the first gate contact layer 24 is used in the third barrier layer 22, the built-in voltage can be increased, thus making it possible to apply a large positive voltage to the gate electrode 20. In addition, the concentration of an n-type impurity of the first barrier layer 15 can be increased, so that an increase in source resistance can be restrained. Accordingly, as the on-state resistance Rₒₙ can be kept low, it is possible to realize a power transistor having optimum low-distortion and high-efficiency properties. Further, an operation in an enhancement mode becomes easy. Furthermore, since the p-type layer is formed by epitaxial growth, the control of the gate threshold voltage V_{g} is easy and, since the second gate contact layer 26 is provided, the contact resistance is reduced.

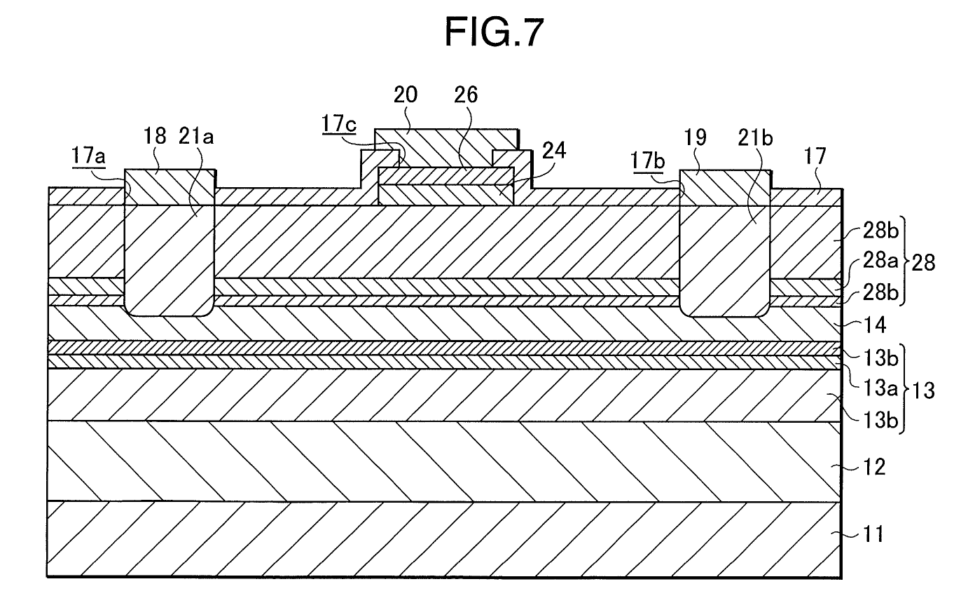

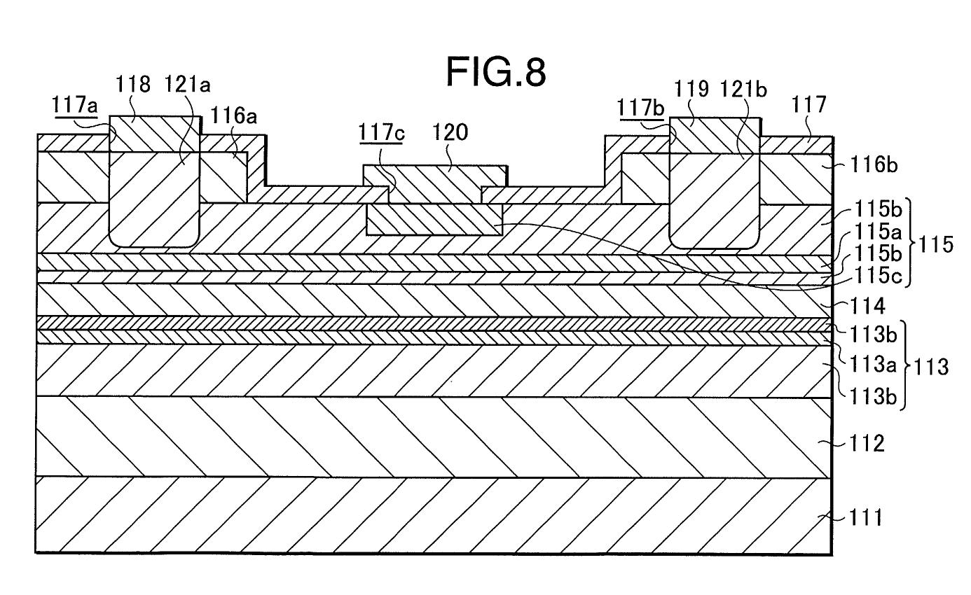

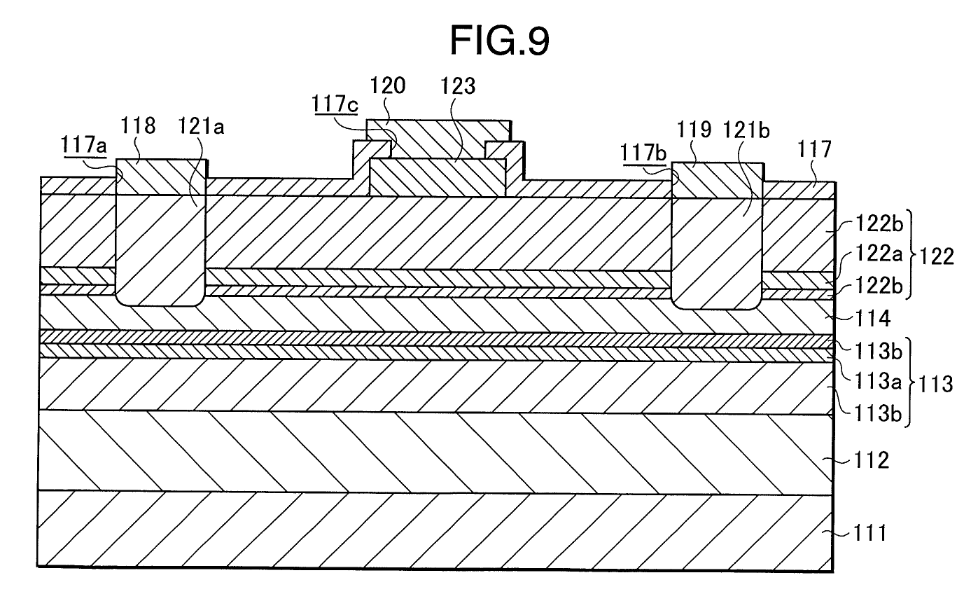

As it can be understood from the above description, when the semiconductor device of this embodiment is used as a power amplifier, the power amplifier has optimum low-distortion and high-efficiency properties and is easily operated by a single positive power source. Therefore, when this semiconductor device is used in a radio communication device, not only can the size of the radio communication device be reduced, but also the power consumption can be reduced. Specifically, if the semiconductor device is used in a portable communication terminal, it is possible to downsize the device and prolong the time of use, thus improving the portability of the terminal. In addition, as a low-distortion property is considered to be important for power amplifiers in new communication systems which can realize high quality of communication such as CDMA and the like, the semiconductor device of this embodiment can be advantageously used in the radio communication system using such new communication systems. Further, as the semiconductor device of this embodiment has optimum low on-state resistance Rₒₙ properties, it can be used as a switch with low-loss properties. Next, the semiconductor device according to the second embodiment of the present invention will be described below with reference to the diagrammatic cross-sectional view of FIG. 7. FIG. 7 shows one example of an n-channel type FET in which the first conductive impurity is of a p-type and the second conductive impurity is of an n-type. In this second embodiment, the semiconductor device has substantially the same construction as that of the first embodiment except that the third barrier layer is omitted, so that the first barrier layer has the function of the third barrier layer.

Specifically, as shown in FIG. 7, in the semiconductor device, for example, a second barrier layer 13, a channel layer 14, a first barrier layer 28, a first gate contact layer 24 and a second gate contact layer 26, each of which comprising a III-V compound semiconductor, are successively stacked on one another on one surface of a substrate 11 comprising a semi-insulating single crystal GaAs, through a buffer layer 12 comprising u-GaAs to which an impurity is not added intentionally. On the portion of the first barrier layer 28 and the second gate contact layer 26 opposite to the side of the substrate 11 that is exposed to the outside is covered by an insulating film 17. Opening portions 17a and 17b are provided in the insulating film 17. A source electrode 18 and a drain electrode 19 are formed on the first barrier layer 28 through, respectively, the opening portions 17a and 17b. Further, an opening portion 17c is provided between the opening portion 17a and the opening portion 17b in the insulating film 17 and, through the opening portion 17c, a gate electrode 20 is formed on the second gate contact layer 26. As a result, in a region between the gate electrode 20 and the source electrode 18 that is nearer to the source electrode 18, the first barrier layer 28 is formed on the uppermost layer among the semiconductor layers.

Each of the second barrier layer 13, the channel layer 14, the first gate contact layer 24, the second gate contact layer 26, the insulating film 17, the source electrode 18 and the drain electrode 19 has the same construction and effect as those in the first embodiment of the present invention. Therefore, parts or portions of the second embodiment that are alike those in the first embodiment are indicated by identical reference numerals or symbols, and, for the second embodiment, detailed description of those parts are omitted.

The first barrier layer 28 comprises a III-V compound semiconductor having an electron affinity smaller and a band-gap wider than that of the IIIV compound semiconductor that constitutes the channel layer 14. This embodiment is provided as to have, further, the sum of the electron affinity and the band-gap of the first barrier layer 28 larger than that of the first gate contact layer 24.

When the channel layer 14 comprises InGaAs and the first gate contact layer 24 comprises AlGaAs, InGaP, AlInGaP, AlGaAs and the like can be mentioned as examples of the above III-V compound semiconductor for the first barrier layer 28 and each of these compound crystals individually have their own advantages.

The first barrier layer 28 comprises an u-In_{0.5}Ga_{0.5}P compound crystal in which the atomic ratio of In of the Group III elements is 0.5 so as to achieve a good lattice matching with the GaAs substrate. Thus, it is possible to seal electrons in the channel layer 14. In addition, in this embodiment, the first gate contact layer 24 comprises Al_{0.35}Ga_{0.65}As, and the sum of the electron affinity and the band-gap of the first barrier layer 28 is larger than that of the first gate contact layer 24. Therefore, a hole can be sealed in the first gate contact layer 24, and thus a large built-in voltage can be yielded.

In this embodiment, Al_{0.35}Ga_{0.65}As is used in the first gate contact layer 24, and, as the content of aluminum in the first gate contact layer 24 is increased, the sum of the electron affinity and the band-gap of the first gate contact layer 24 exceed that of the In_{0.5}Ga_{0.5}P at a certain point, called a crossover point. Such a crossover point is presumed to be around an aluminum content of 0.6. Therefore, as for obtaining the effect described in this embodiment, the content of aluminum in the first gate contact layer 24 is required to be 0.6 or less.

Also when the sum of the electron affinity and the band-gap of the first gate contact layer 24 is larger than that of the In_{0.5}Ga_{0.5}P, the sum of the electron affinity and the band-gap of the first barrier layer 28 can be increased by using AlInGaP in the first barrier layer 28. However, in such case, it becomes difficult to selectively remove the first gate contact layer 24.

In_{0.5}Ga_{0.5}P and AlInGaP can be used, respectively, in the first gate contact layer 24 and the first barrier layer 28. In this case, it is possible to make the sum of the electron affinity and the band-gap of the first barrier layer 28 larger than that of the first gate contact layer 24, and, at the same time it is possible to selectively remove the first gate contact layer 24. In the first gate contact layer 24, it is desirable that the atomic ratio of In of the Group III elements is equal or more than 0.4 and equal or less than 0.6. When the atomic ratio of In of the Group III elements is less than 0.4 or more than 0.6, the lattice mismatch between the first gate contact layer 24 and the GaAs substrate becomes too large.

Although it is possible to use AlGaAs having an aluminum content larger than that of the first gate contact layer 24 in the first barrier layer 28, it becomes difficult to selectively remove the first gate contact layer 24.

The first barrier layer 28 has a second conductive high-concentration impurity addition region 28a containing an n-type impurity in a high concentration, and a low impurity-concentration region 28b having a low impurity concentration and a high resistance. In this embodiment, the first barrier layer 28 has a structure such that, for example, the low impurity-concentration region 28b having a thickness of 2 nm and to which no impurity has been added, the second conductive high-concentration impurity addition region 28a having a thickness of 6 nm to which silicon as an n-type impurity is added in a concentration of, for example, about 2.7×10¹² particles/cm², and the low impurity-concentration region 28b having a thickness of 12 nm and to which no impurity has been added are successively stacked on one another in this order from the side of the channel layer 14. The low impurity-concentration region 28b may contain a small amount of an impurity, as compared to the second conductive high-concentration impurity addition region 28a.

It is desirable that the impurity concentration of the low impurity-concentration region 28b is 2×10¹⁷ particles/cm³ or less. When the concentration exceeds this value, the electron transit velocity through the channel layer 14 is remarkably lowered in a region adjacent to the channel layer, and the gate voltage endurance is remarkably lowered in a region near the gate.

As mentioned above, a remarkable difference between the first embodiment and the second embodiment resides in that, in the second embodiment, the first barrier layer has the functions of the third barrier layer, and thus, the third barrier layer is omitted.

As mentioned below, the semiconductor device of the second embodiment has the same effect of the semiconductor device of the first embodiment. Specifically, a large gate built-in voltage can be yielded, therefore allowing a large positive voltage to be applied to the gate electrode 20, and this is advantageous from the viewpoint of achieving an operation only by a positive regulator. In addition, as for realizing the same gate threshold voltage Vₜₕ under the same film thickness conditions, it is necessary to increase the sheet doping concentration of the n-type impurity in the first barrier layer 28 and thus, it becomes possible to restrain the deterioration of the source resistance which is susceptible to occur in the FET structure. In addition, in a region in which the first barrier layer 28 is formed as the uppermost surface among the semiconductor layers between the gate electrode 20 and the source electrode 18, it is possible to form a layer on the surface portion of the first barrier layer 28 containing at least one element selected from selenium, sulfur and silicon in a high concentration. Further, as the discontinuity amount ΔE_{c} of conduction band edge between the channel layer 14 and the first barrier layer 28 is satisfactorily large, for the same reason as that in the first embodiment, the mutual conductance Gₘ hardly suffers deterioration during the application of a gate voltage, and, when the semiconductor device is used as a power element, it is possible to realize a device also having optimum low-distortion properties.

In addition, also in this semiconductor device, the second gate contact layer 26 comprising p-GaAs is provided so that a problem of the increase in contact resistance does not arise.

The semiconductor device having the above-mentioned construction operates in the same manner as in the first embodiment, has the same effect, and therefore, it can be used in a similar way.

Hereinabove, the preferred embodiments of the present invention are described, however the present invention is not limited to the above embodiments and can be modified. For example, in the above embodiments, especially in the first embodiment, the semiconductor device is in an enhancement mode in which the gate threshold voltage Vₜₕ is about 0 V, but the semiconductor device of the present invention can be in a depletion mode. In addition, in each of the above embodiments, the semiconductor device is an n-channel type FET in which the first conductive impurity is of a p-type and the second conductive impurity is of an n-type, but the semiconductor device of the present invention can be a p-channel type FET in which the first conductive impurity is of an n-type and the second conductive impurity is of a p-type.

Yet, in each of the above embodiments, the second conductive high-concentration impurity addition regions 13a, 15a and 28a are provided on both the second barrier layer 13 and the first barrier layer 15 or 28, but the second conductive high-concentration impurity addition region may be provided on any one of either the second barrier layer 13 or the first barrier layer 15 or 28.

Further, in each of the above embodiments, the first barrier layer 15 or 28 and the second barrier layer 13 contain the second conductive high-concentration impurity addition regions 15a, 28a and 13a, and an impurity is not added intentionally to the channel layer 14, however, instead of adding the second conductive impurity to the channel layer 14, it is possible not to add an impurity intentionally to the first barrier layer 15 or 28 and the second barrier layer 13. Alternatively, the second conductive impurity addition regions may be provided for all of the channel layer 14, the first barrier layer 15 or 28 and the second barrier layer 13.

Furthermore, in each of the above embodiments, the second barrier layer 13 is provided on the first barrier layer 15 or 28 on the opposite side of the channel layer 14, but the present invention also encompasses a semiconductor device lacking the second barrier layer 13.

Further, in each of the above embodiments, the III-V compound semiconductors constituting the respective constituents are explained in detail, but the constituents may comprise other III-V compound semiconductors. In addition, they may comprise semiconductors other than the III-V compound semiconductors. For example, in the present invention, an explanation is mainly on the case in which the channel layer 14 comprises InGaAs, the first barrier layer 15 or 28 comprises AlGaAs or InGaP, the first gate contact layer 24 comprises AlGaAs, and the second gate contact layer 26 comprises GaAs, however, in each of the first and third barrier layers, a compound crystal, such as AlInGaP or the like, can be used. In addition, in the channel layer 14, a material containing nitrogen (N), such as InGaN, InGaAsN or the like, can be used. By using these materials, it is possible to further increase the discontinuity amount ΔE_{c} of the conduction band edge between the channel layer 14 and the first barrier layer 15 or 28 adjacent to the channel layer and, as a result, a change in the mutual conductance Gₘ and a change in the gate-source capacitance C_{gs} can be reduced over a wide range of the gate voltage, and this is advantageous from the viewpoint of achieving high output and optimum low-distortion and high-efficiency properties of the power amplifier. In the present specification, an expression reading “sum of an electron affinity and a band-gap” is frequently used, and this expression means an energy level of the valence band edge measured from the vacuum level. The “sum of an electron affinity and a band-gap” in an n-channel type FET, i.e., FET in which the second conductive impurity is of an n-type corresponds to the energy level of the conduction band edge measured from the vacuum level, i.e., “electron affinity” in a p-channel type FET. Further, an expression reading “the sum of an electron affinity and a band-gap is large” in the n-channel type FET corresponds to an expression reading “an electron affinity is small” in the p-channel type FET. Conversely, an expression reading “an electron affinity is large” in the n-channel type FET corresponds to an expression reading “the sum of an electron affinity and a band-gap is small” in the p-channel type FET.

What is claimed is:

1. A semiconductor device, comprising:
a channel layer formed on a substrate, said channel layer comprising a semiconductor;
a first barrier layer formed on said channel layer, said first barrier layer comprising a semiconductor which has an electron affinity smaller than that of the semiconductor constituting said channel layer;
a first gate contact layer formed on said first barrier layer, said first gate contact layer having a first conductive low-resistance region comprising a semiconductor containing a first conductive impurity in a high concentration, wherein the sum of an electron affinity and a band-gap of said first gate contact layer is larger than an electron affinity of said channel layer by 1.3 eV or more;
a gate electrode formed on said first gate contact layer; and
a source electrode and a drain electrode formed on said first barrier layer with said gate electrode interposed, wherein
said channel layer serves as a current passage between said source electrode and said drain electrode.

2. The semiconductor device according to claim 1, wherein
the sum of an electron affinity and a band-gap of said first barrier layer is larger than that of said first gate contact layer.

3. The semiconductor device according to claim 1, further comprising:
a second barrier layer formed on an opposite side of said first gate contact layer with said channel layer interposed, said second barrier layer comprising a semiconductor which has an electron affinity smaller than that of the semiconductor constituting said channel layer.

4. The semiconductor device according to claim 1, further comprising:
a third barrier layer formed between said first gate contact layer and said first barrier layer, wherein
the sum of an electron affinity and a band-gap of said third barrier layer is larger than that of said first gate contact layer.

5. The semiconductor device according to claim 1, further comprising:
a second gate contact layer formed between said gate electrode and said first gate contact layer, wherein
the sum of an electron affinity and a band-gap of said second gate contact layer is smaller than that of said first gate contact layer.

6. The semiconductor device according to claim 1, wherein
said source electrode and said drain electrode are formed on said first barrier layer, and
said first barrier layer has a second conductive low-resistance region corresponding to said source electrode and said drain electrode.

7. The semiconductor device according to claim 4, wherein
said source electrode and said drain electrode are formed on said third barrier layer, and
said third barrier layer has a second conductive low-resistance region corresponding to said source electrode and said drain electrode.

8. The semiconductor device according to claim 1, wherein
at least one barrier layer selected from the group consisting of said first barrier layer and said second barrier layer contains a second conductive impurity in a high concentration in the vicinity of said channel layer.

9. The semiconductor device according to claim 1, wherein
said channel layer comprises an indium gallium arsenide compound crystal that is a compound semiconductor of classification group III-V.

10. The semiconductor device according to claim 9, wherein
an atomic ratio of indium of the classification Group III elements contained in the indium gallium arsenide compound crystal constituting said channel layer is equal or more than 0.1 and equal or less than 0.4.

11. The semiconductor device according to claim 1, wherein
said first gate contact layer comprises an aluminum gallium arsenide compound crystal that is a compound semiconductor of classification group III-V.

12. The semiconductor device according to claim 11, wherein
an atomic ratio of aluminum of the Group III elements contained in the aluminum gallium arsenide compound crystal constituting said first gate contact layer is equal or more than 0.3 and equal or less than 0.7.

13. The semiconductor device according to claim 1, wherein
said first gate contact layer comprises an indium gallium phosphorus compound crystal which is a compound semiconductor of classification group III-V.

14. The semiconductor device according to claim 13, wherein
an atomic ratio of indium of the Group III elements contained in the indium gallium phosphorus compound crystal constituting said first gate contact layer is equal or more than 0.4 and equal or less than 0.6.

15. The semiconductor device according to claim 1, wherein
said first barrier layer comprises an aluminum gallium arsenide compound crystal that is a compound semiconductor of classification group III-V.

16. The semiconductor device according to claim 1, wherein
said first barrier layer comprises an indium gallium phosphorus compound crystal which is a compound semiconductor of classification group III-V.

17. The semiconductor device according to claim 16, wherein
an atomic ratio of indium of the Group III elements contained in the indium gallium phosphorus compound crystal constituting said first barrier layer is equal or more than 0.4 and equal or less than 0.6.

18. The semiconductor device according to claim 4, wherein
said third barrier layer comprises an indium gallium phosphorus compound crystal which is a compound semiconductor of classification group III-V.

19. The semiconductor device according to claim 18, wherein
an atomic ratio of indium of the Group III elements contained in the indium gallium phosphorus compound crystal constituting said third barrier layer is equal or more than 0.4 and equal or less than 0.6.

20. The semiconductor device according to claim 4, wherein
said third barrier layer comprises an aluminum indium gallium phosphorus compound crystal which is a compound semiconductor of classification group III-V.

21. The semiconductor device according to claim 5, wherein
said second gate contact layer comprises a gallium arsenide compound crystal which is a compound semiconductor of classification group III-V.

22. The semiconductor device according to claim 3, wherein
said second barrier layer comprises an aluminum gallium arsenide compound crystal which is a compound semiconductor of classification group III-V.

23. The semiconductor device according to claim 1, wherein
said first conductive impurity contained in said first gate contact layer comprises at least one element selected from the group consisting of carbon, zinc, magnesium and beryllium.

24. The semiconductor device according to claim 5, wherein
said first conductive impurity contained in said second gate contact layer comprises at least one element selected from the group consisting of carbon, zinc, magnesium and beryllium.

25. The semiconductor device according to claim 1, wherein
said channel layer comprises a compound semiconductor containing nitrogen.

26. The semiconductor device according to claim 8, wherein
said second conductive impurity comprises at least one element selected from the group consisting of selenium, silicon, germanium, tin and sulfur.

27. The semiconductor device according to claim 1, wherein
said first barrier layer is formed on the uppermost surface layer of the semiconductor layers in a region between said gate electrode and said source electrode that is in the vicinity of said source electrode.

28. The semiconductor device according to claim 27, wherein
in a region between said gate electrode and said source electrode, in which said first barrier layer is formed on the uppermost surface layer of the semiconductor layers, said first barrier layer contains at least one element selected from the group consisting of selenium, sulfur and silicon in a high concentration at a surface layer portion thereof.

29. The semiconductor device according to claim 4, wherein
said third barrier layer is formed on the uppermost surface layer of the semiconductor layers in a region between said gate electrode and said source electrode and near said source electrode.

30. The semiconductor device according to claim 29, wherein
in a region between said gate electrode and said source electrode, in which said third barrier layer is formed on the uppermost surface layer of the semiconductor layers, said third barrier layer contains at least one element selected from the group consisting of selenium, sulfur and silicon in a high concentration at a surface layer portion thereof.

31. A process for fabricating a semiconductor device, comprising the steps of:
forming, on a substrate, of a channel layer comprising a semiconductor;
forming, on said channel layer, of a first barrier layer comprising a semiconductor which has an electron affinity smaller than that of the semiconductor constituting said channel layer;
forming, on said first barrier layer, of a first gate contact layer having a first conductive low-resistance region which comprises a semiconductor containing a first conductive impurity in a high concentration, wherein the sum of an electron affinity and a band-gap of said first gate contact layer is larger than an electron affinity of said channel layer by 1.3 eV or more;
forming of a gate electrode on said first gate contact layer; and
forming a source electrode and a drain electrode on said first barrier layer with said gate electrode interposed, wherein
said channel layer serves as a current passage between said source electrode and said drain electrode.

31. The process according to claim 31, wherein
said first barrier layer and said first gate contact layer are formed so that the sum of an electron affinity and a band-gap of said first barrier layer becomes larger than that of said first gate contact layer.

32. The process according to claim 31, further comprising a step of:
before forming of said channel layer, forming, on said substrate, a second barrier layer comprising a semiconductor which has an electron affinity smaller than that of the semiconductor constituting said channel layer.

33. The process according to claim 31, further comprising a step of:
after forming of said first barrier layer and before forming of said first gate contact layer, forming of a third barrier layer on said first barrier layer, wherein
the sum of an electron affinity and a band-gap of said third barrier layer is larger than that of said first gate contact layer.

34. The process according to claim 31, further comprising a step of:
after forming of said first gate contact layer and before forming of said gate electrode, forming of a second gate contact layer, wherein
the sum of an electron affinity and a band-gap of said second gate contact layer is smaller than that of said first gate contact layer.

35. The process according to claim 31, wherein
when said source electrode and said drain electrode are formed on said first barrier layer, a second conductive low-resistance region corresponding to said source electrode and said drain electrode is formed on said first barrier layer.

36. The process according to claim 34, wherein
when said source electrode and said drain electrode are formed on said third barrier layer, a second conductive low-resistance region corresponding to said source electrode and said drain electrode is formed on said third barrier layer.

37. The process according to claim 31, further comprising a step of:
forming of a layer containing a second conductive impurity in a high concentration in at least one barrier layer selected from the group consisting of said first barrier layer and said second barrier layer in the vicinity of said channel layer.

38. The process according to claim 31, wherein
said channel layer is formed from an indium gallium arsenide compound crystal which is a compound semiconductor of classification group III-V.

39. The process according to claim 39, wherein
an atomic ratio of indium of the Group III elements contained in the indium gallium arsenide compound crystal constituting said channel layer is equal or more than 0.1 and equal or less than 0.4.

40. The process according to claim 31, wherein
said first gate contact layer is formed from an aluminum gallium arsenide compound crystal which is a compound semiconductor of classification group III-V.

41. The process according to claim 41, wherein
an atomic ratio of aluminum of the Group III elements contained in the aluminum gallium arsenide compound crystal constituting said first gate contact layer is equal or more than 0.3 and equal or less than 0.7.

42. The process according to claim 31, wherein
said first gate contact layer is formed from an indium gallium phosphorus compound crystal which is a compound semiconductor of classification group III-V.

43. The process according to claim 43, wherein
an atomic ratio of indium of the Group III elements contained in the indium gallium phosphorus compound crystal constituting said first gate contact layer is equal or more than 0.4 and equal or less than 0.6.

44. The process according to claim 31, wherein
said first barrier layer is formed from an aluminum gallium arsenide compound crystal which is a compound semiconductor of classification group III-V.

45. The process according to claim 31, wherein
said first barrier layer is formed from an indium gallium phosphorus compound crystal which is a compound semiconductor of classification group III-V.

46. The process according to claim 46, wherein
an atomic ratio of indium of the Group III elements contained in the indium gallium phosphorus compound crystal constituting said first barrier layer is equal or more than 0.4 and equal or less than 0.6.

48. The process according to claim 34, wherein said third barrier layer is formed from an indium gallium phosphorus compound crystal which is a compound semiconductor of classification group III-V.

49. The process according to claim 48, wherein
an atomic ratio of indium of the Group III elements contained in the indium gallium phosphorus compound crystal constituting said third barrier layer is equal or more than 0.4 and equal or less than 0.6.

50. The process according to claim 34, wherein
said third barrier layer is formed from an aluminum indium gallium phosphorus compound crystal which is a compound semiconductor of classification group III-V.

51. The process according to claim 35, wherein
said second gate contact layer is formed from a gallium arsenide compound crystal which is a compound semiconductor of classification group III-V.

52. The process according to claim 33, wherein
said second barrier layer is formed from an aluminum gallium arsenide compound crystal which is a compound semiconductor of classification group III-V.

53. The process according to claim 31, wherein
at least one element selected from the group consisting of carbon, zinc, magnesium and beryllium is used as said first conductive impurity contained in said first gate contact layer.

54. The process according to claim 35, wherein
at least one element selected from the group consisting of carbon, zinc, magnesium and beryllium is used as said first conductive impurity contained in said second gate contact layer.

55. The process according to claim 31, wherein
said channel layer is formed from a compound semiconductor containing nitrogen.

56. The process according to claim 38, wherein
at least one element selected from the group consisting of selenium, silicon, germanium, tin and sulfur is used as said second conductive impurity.

57. The process according to claim 31, wherein
said first barrier layer is formed on the uppermost surface layer of the semiconductor layers in a region between said gate electrode and said source electrode that is in the vicinity of said source electrode.

58. The process according to claim 57, wherein
in a region between said gate electrode and said source electrode, in which said first barrier layer is formed on the uppermost surface layer of the semiconductor layers, said first barrier layer contains at least one element selected from the group consisting of selenium, sulfur and silicon in a high concentration at a surface layer portion thereof.

59. The process according to claim 34, wherein
said third barrier layer is formed on the uppermost surface layer of the semiconductor layers in a region between said gate electrode and said source electrode that is in the vicinity of said source electrode.

60. The process according to claim 59, wherein
in a region between said gate electrode and said source electrode, in which said third barrier layer is formed on the uppermost surface layer of the semiconductor layers, said third barrier layer contains at least one element selected from the group consisting of selenium, sulfur and silicon in a high concentration at a surface layer portion thereof.
